(19) United States
(12) Patent Application Publication
(10) Pub. No.: US 2008/0220379 A1
(43) Pub. Date: Sep. 11, 2008

(54) PATTERN FORMING METHOD AND PATTERN FORMATION APPARATUS

(75) Inventor: Yoichi NOMURA, Tokyo (JP)

Correspondence Address: Young & Thompson, 209 Madison Street, Suite 500, Alexandria, VA, 22314, US

(73) Assignee: ELPIDA MEMORY, INC., Tokyo (JP)

(21) Appl. No.: 12/042,374

(22) Filed: Mar. 5, 2008

(30) Foreign Application Priority Data
Mar. 7, 2007 (JP) 2007-056912

(51) Int. Cl. G03B 27/52; G03F 7/26

(52) U.S. Cl. 430/322; 355/27

(57) ABSTRACT

The present invention provides a pattern forming method and a pattern formation apparatus capable of suppressing variations in line width dimensions of a resist pattern. The pattern forming method of the present invention is a pattern forming method comprising a first step for coating a photoresist onto a wafer W, a second step for selectively exposing the wafer W coated with the photoresist, a third step for carrying out baking treatment on the exposed wafer W, and a fourth step for carrying out development treatment on the baked wafer W; wherein, in the third step, the baking treatment is carried out by forming a first atmosphere containing at least moisture, and then replacing the first atmosphere and forming a second atmosphere not containing moisture, followed by continuing the baking treatment.

### BACKGROUND OF THE INVENTION

1. Field of the Invention

The present invention relates to a method for forming a pattern in the production of a semiconductor device and to a pattern formation apparatus, and more particularly, to a technology for suppressing variations in the dimensions of a resist pattern.

The present application claims priority on Japanese Patent Application No. 2007-056912, filed on Mar. 7, 2007, the content of which is incorporated herein by reference.

2. Description of the Related Art

In the production process of a semiconductor device, a plurality of circuits are formed on a disk-shaped substrate (wafer) made of silicon, and these circuits are then cut apart to produce semiconductor elements.

The pattern formation of these circuits is carried out by a photolithography step, and in general, after having coated various layers consisting of a silicon dioxide film, silicon nitride film or polysilicon film and the like on the surface of the wafer and further coating a photoresist onto the surface of the formed wafer in the form of a film followed by heating to cure the photoresist film, the wafer is exposed through a photomask and developed, thereby enabling an element or circuit pattern depicted in the photomask to be transferred to the photoresist film.

Although there are “positive type” photoresists, in which the exposed portion dissolves, and “negative type” photoresists, in which the exposed portion remains, the positive type photoresists are said to be advantageous for obtaining fine patterns.

In either case, when subjected to development treatment following exposure, the unwanted portion of the photoresist is removed resulting in the appearance of the resist pattern on the wafer.

By then using this resist pattern to further carry out etching, film deposition or lift-off and the like, a target circuit can be produced on the wafer.

Accompanying the increased fineness of semiconductors in recent years, in addition to reductions in the minimum line width required for resist patterns, KrF, ArF and other short-wavelength excimer lasers have come to be commonly used for exposure light source. Chemically amplified photoresists are commonly used in cases of weak exposure intensity when using these short-wavelength exposure light sources.

Positive type chemically amplified photoresists are composed of a photo acid generator (PAG) and a resin in which functional groups, such as hydroxyl groups or carboxyl groups that are soluble in an alkaline developing solution, are substituted with a certain type of compound (protecting groups), and the photo acid generator decomposes due to exposure.

The decomposed photo acid generator reacts with moisture in the air to form hydrogen ions (H⁺), and these H⁺ ions trigger an elimination reaction resulting in the elimination of protecting groups attached to the resist resin by means of an acid-catalyzed reaction. The protecting groups then decompose to form H⁺ ions, which further triggers the elimination of other protecting groups. Thus, H⁺ ions become diffused in the resist matrix resulting in successive progression of the protecting group decomposition reaction.

Since the resist resin from which protecting groups have been eliminated is soluble in an alkaline developing solution, a latent image is formed on the resist pattern by exposure, and a desired resist pattern can be formed by subsequent development treatment.

This series of acid-catalyzed reactions is promoted by heat treatment following exposure referred to as post-exposure bake (to be simply referred to as PEB). PEB at high temperature increases the reaction rate of the acid-catalyzed reactions, and PEB treatment for a long time increases the amount of the acid-catalyzed reaction. Consequently, these acid-catalyzed reactions are controlled by treatment conditions such as the temperature and treatment time during PEB.

However, since chemically amplified photoresists are highly reactive with other acids and bases, and react sharply to trace amounts of ammonia, for example, exposure and development treatment in a short period of time in a clean room, and particularly a clean environment using a chemical filter and the like, is preferable in terms of stably retaining the properties thereof.

Consequently, in a photolithography step involving the handling of a chemically amplified photoresist in particular, an inline system pattern formation apparatus is used that integrates, for example, a resist coater for coating the photoresist onto a wafer, an exposure apparatus such as a scanner, a baking apparatus for carrying out PEB treatment, a developer for carrying out development treatment and transport apparatus for transporting the wafer between each of these apparatuses. This apparatus is typically the single wafer processing type in which a plurality of wafers are treated while transporting in lot units to form a resist pattern in a predetermined short time.

The baking apparatus for carrying out PEB treatment is typically composed of a unit provided with a hot plate, a chamber, an exhaust port and a gas supply line. The hot plate is covered with the chamber, and PEB treatment is carried out within the chamber isolated from outside air. At that time, gas generated from the wafer is discharged from the exhaust port, while chemically and moisture-controlled air is taken in from the gas supply line to prevent the generation of negative pressure by the hot plate due to this discharge of gas.

Although control of acid-catalyzed reactions is carried out based on the treatment conditions at the time of PEB treatment as previously described, these reactions are also controlled on the basis of not only temperature or treatment time but also humidity.

For example, Japanese Unexamined Patent Application, First Publication No. H9-320930 described a method for carrying out PEB treatment while feeding air at a temperature of 23° C. and humidity of 45 to 55%.

In addition, Japanese Unexamined Patent Application, First Publication No. H10-208997 describes a method for carrying out PEB treatment while maintaining the humidity in a chamber at about 45% by introducing humidified nitrogen gas into the chamber.

However, in the case a plurality of hot plates are present in a pattern formation apparatus, it was difficult to uniformly control PEB treatment temperature and treatment time among the plurality of hot plates.

For example, there was the problem of fluctuations in hot plate temperature caused by wafer transport and the like. In addition, with respect to treatment time as well, there was the problem of the treatment time being different for each wafer processed in each unit. As a result, there was the problem of differences in the dimensions of the resist pattern between wafers from the same lot, or in other words, dimensional variation.

### SUMMARY OF THE INVENTION

In consideration of these circumstances, an object of the present invention is to provide a pattern forming method and pattern formation apparatus that makes it possible to suppress variations in line width dimensions of resist patterns.

In order to solve the aforementioned problems, the pattern forming method of the present invention comprises: a first step for coating a photoresist onto a substrate, a second step for selectively exposing the substrate coated with the photoresist, a third step for carrying out baking treatment on the exposed substrate, and a fourth step for carrying out development treatment on the baked substrate; wherein, in the third step, the baking treatment is carried out by forming a first atmosphere containing at least moisture, and then replacing the first atmosphere and forming a second atmosphere not containing moisture, followed by continuing the baking treatment.

In addition, in the pattern forming method of the present invention, the first atmosphere is formed from a gas humidified to a humidity of 44 to 46%, and the second atmosphere is an inert gas atmosphere.

In addition, in the third step of the pattern forming method of the present invention, the first atmosphere and the second atmosphere are formed for each of a plurality of the exposed substrates.

The pattern formation apparatus of the present invention is a pattern formation apparatus that carries out a first step for coating a photoresist onto a substrate, a second step for selectively exposing the substrate coated with the photoresist, a third step for carrying out baking treatment on the exposed substrate, and a fourth step for carrying out development treatment on the baked substrate; wherein the apparatus comprises at least one unit including a heating section for heating the exposed substrate by placing thereon, a chamber for covering the heating section, an exhaust unit for discharging gas within the chamber to the outside, and a gas supply mechanism for supplying a gas inside the chamber, and the air supply mechanism in the third step is able to supply a first gas containing at least moisture and then switch to supplying a second gas not containing moisture, and the baking treatment is carried out by forming a first atmosphere consisting of the first gas and then replacing the first atmosphere and forming a second atmosphere consisting of the second gas, followed by continuing the baking treatment.

In addition, in the pattern formation apparatus of the present invention, the first gas is a gas humidified to a humidity of 44 to 46%, and the second gas is an inert gas.

In addition, the pattern formation apparatus of the present invention is provided with a plurality of the units, and has the ability to control the supply of the gas for each of the units.

As has been explained above, according to the present invention, as a result of employing a pattern forming method that comprises a first step for coating a photoresist onto a substrate, a second step for selectively exposing the substrate coated with the photoresist, a third step for carrying out baking treatment on the exposed substrate, and a fourth step for carrying out development treatment on the baked substrate, carrying out the baking treatment in the third step by forming a first atmosphere containing at least moisture, and then replacing the first atmosphere and forming a second atmosphere not containing moisture followed by continuing the baking treatment, the atmosphere can be switched during the course of heat treatment, thereby making it possible to control an acid-catalyzed reaction of a chemically amplified photoresist not only by the temperature and treatment time of the heat treatment, but also by the atmosphere.

In addition, since the first atmosphere is formed from a gas humidified to a humidity of 44 to 46%, and the second atmosphere is an inert gas atmosphere, the acid-catalyzed reaction can be precisely controlled since moisture serving as the initiator of the acid-catalyzed reaction is supplied from the first atmosphere while the acid-catalyzed reaction is terminated by the second atmosphere.

In addition, as a result of forming the first atmosphere and the second atmosphere for each of a plurality of exposed substrates in the third step, the acid-catalyzed reaction can be precisely controlled for each exposed substrate, thereby making it possible to suppress variations in line width dimensions of resist patterns among the exposed substrates.

According to the pattern formation apparatus of the present invention, as a result of carrying out a first step for coating a photoresist onto a substrate, a second step for selectively exposing the substrate coated with the photoresist, a third step for carrying out baking treatment on the exposed substrate, and a fourth step for carrying out development treatment on the baked substrate; wherein the apparatus comprises at least one unit including a heating section for heating the exposed substrate by placing thereon, a chamber for covering the heating section, an exhaust unit for discharging gas within the chamber to the outside, and providing a gas supply mechanism for supplying a gas inside the chamber, and the air supply mechanism in the third step is able to supply a first gas containing at least moisture and then switch to supplying a second gas not containing moisture, and the baking treatment is carried out by forming a first atmosphere consisting of the first gas and then replacing the first atmosphere and forming a second atmosphere consisting of the second gas, followed by continuing the baking treatment, in the third step, heat treatment can be carried out by the formed first atmosphere, and heat treatment can then be continued by the formed second atmosphere composed of a different gas to the first atmosphere, thereby making it possible to control an acid-catalyzed reaction of a chemically amplified photoresist not only by the temperature and treatment time of the heat treatment, but also by the atmosphere.

In addition, since the first gas is formed from a gas humidified to a humidity of 44 to 46%, and the second gas is an inert gas, the acid-catalyzed reaction can be precisely controlled since moisture serving as the initiator of the acid-catalyzed reaction is supplied from the first gas while the acid-catalyzed reaction is terminated by the second gas.

In addition, as a result of the pattern formation apparatus of the present invention being provided with a plurality of the units, and has the ability to control the supply of the gas for each of the units, the acid-catalyzed reaction can be precisely controlled for each exposed substrate, thereby making it possible to suppress variations in line width dimensions of resist patterns among the exposed substrates.

### BRIEF DESCRIPTION OF THE DRAWINGS

FIG. 1 is a cross-sectional view of a unit of a pattern formation apparatus in an embodiment of the present invention;

FIG. 2 is a cross-sectional view of a wafer W in an embodiment of the present invention, and indicates the carrying out of a pre-first step (a) and post-first step (b) along with a second step (c); and

FIG. 3 is a cross-sectional view of a wafer W of an embodiment of the present invention, and indicates the carrying out of a third step (a) and (b) and a fourth step (c).

### BRIEF DESCRIPTION OF THE REFERENCE NUMERALS

1: unit, 2: hot plate, 3: chamber, 4: exhaust port, 5: gas supply line, 5a: first gas supply pipe, 5b: second gas supply pipe, 6: first valve, 7: second valve, 8: substrate, 9: hard mask, 10: resist film, 10a: exposed portion, 10b: unexposed portion, 11: photomask, 11a: mask pattern, 12: resist pattern

### DETAILED DESCRIPTION OF THE INVENTION

The following provides an explanation of an embodiment of the present invention.

First, an explanation of the chemical mechanism of the resist pattern is provided.

A chemically amplified positive type photoresist (to be referred to as the “resist”) is composed of a resin, in which functional groups such as hydroxyl groups or carboxyl groups soluble in an alkaline developing solution are substituted with a certain compound (protecting groups), and a photo acid generator (PAG).

The following explanation uses the example of a polyhydroxystyrene (PHS) resin system for KrF using tertiary-butoxycarbonyl groups (t-BOC) for the protecting groups. Here, the photo acid generator is decomposed by exposure to light, and as shown in the following chemical formula (1), the decomposed photo acid generator reacts with water in the air to generate hydrogen ions (H⁺). X⁻ represents the anion of the photo acid generator.

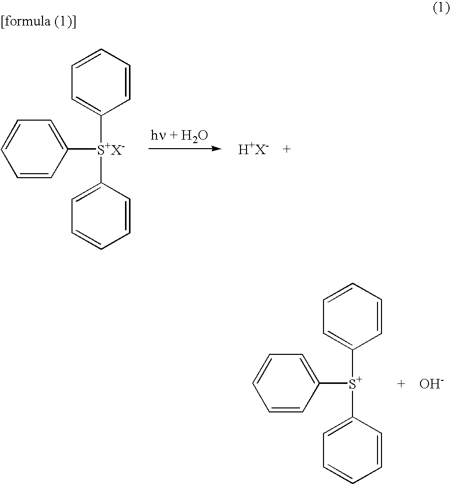

These hydrogen ions (H⁺) function as an acid catalyst, causing the protecting groups (t-BOC in this case) to undergo an elimination reaction as shown in the following chemical formula (2) as a result of the bonds between the resist resin and the protecting groups being hydrolyzed by the heat during post-exposure bake (PEB) treatment.

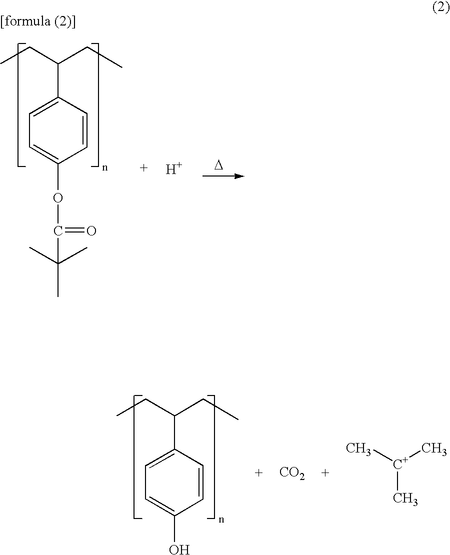

Moreover, the protecting groups decompose to form hydrogen ions (H⁺) that further triggers elimination of other protecting groups.

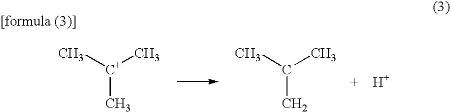

In this manner, hydrogen ions (H⁺) diffuse throughout the resist matrix resulting in successive progression of the protecting group decomposition reaction.

Since functional groups soluble in developing solution (in this case, hydroxyl groups —OH) of the resist resin itself are exposed, the resist resin of which the protecting groups are eliminated becomes soluble in the alkaline developing solution, thereby causing the exposed portion to be removed by the developing solution and allowing the formation of a desired resist pattern.

Continuing, an explanation is provided of a pattern formation apparatus of the present embodiment with reference to the drawings.

The pattern formation apparatus of the present embodiment is an example of a single wafer processing type of pattern formation apparatus employing an inline system integrating a resist coater for coating a resist onto a wafer W, an exposure apparatus for baking a pattern, a baking apparatus for carrying out PEB treatment, a developer for carrying out development treatment and transport apparatus and the like for transporting the wafer W between each of these apparatuses.

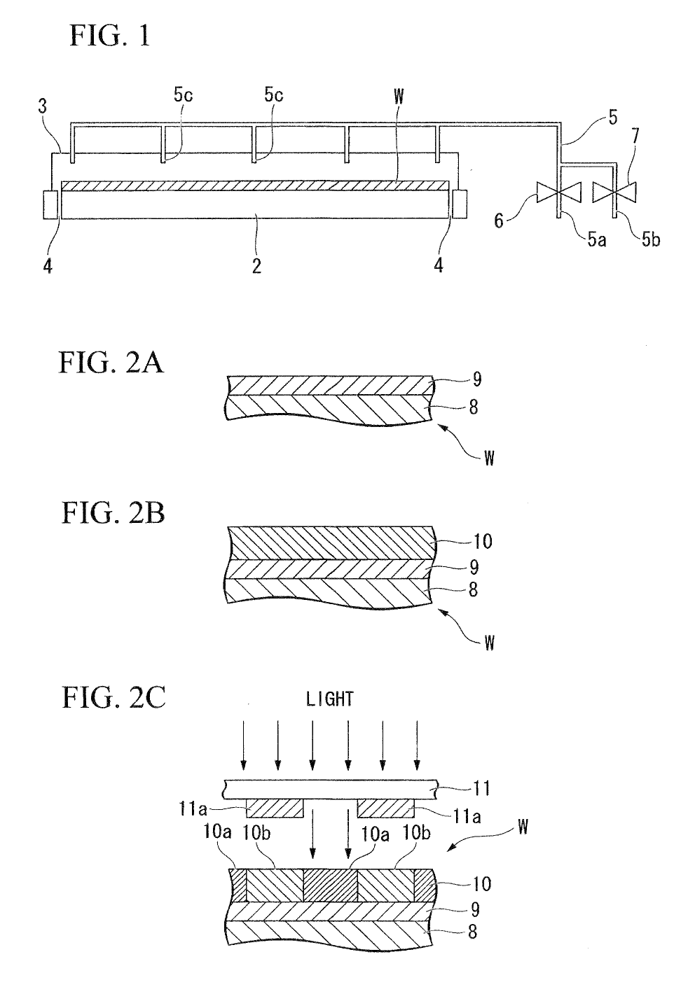

The baking apparatus for carrying out PEB treatment is provided with a plurality of units 1 as shown in FIG. 1, and each unit 1 is provided with a hot plate (heating apparatus) 2, a chamber 3, an exhaust port 4 for discharging gas, and a gas supply line 5, and the atmosphere inside the chamber 3 can be adjusted for each unit 1.

One end of the gas supply line 5 is divided into two branches, with a first gas supply pipe 5a being provided on one branch thereof and a second gas supply pipe 5b being provided on the other branch. The other end of the gas supply line 5 is divided into five branches when viewed from the side (gas feed inlets 5c are divided into a plurality of branches so as to be uniformly arranged on the upper surface of the hot plate 2 when viewed from above), and each end thereof is provided with a gas feed inlet 5c.

The first gas supply pipe 5a is provided with a first valve 6, the second gas supply pipe 5b is provided with a second valve 7, and flow rate of gas supplied to each can be regulated.

The hot plate 2 is provided with a circular stand slightly larger than the outer periphery of a wafer W to be treated, and an exothermic apparatus such as a heater housed in the top of the stand, and a wafer W placed on the stand can be heated to a target temperature while controlling the heating temperature with the exothermic apparatus.

The chamber 3 is provided so as to cover the hot plate 2 and the wafer W, and enables PEB treatment to be carried out on the wafer W while forming a stable atmosphere by isolating the inside of the chamber 3 from the outside air and other components of the unit 1.

The exhaust port 4 is provided in the outer periphery of the hot plate 2 so as to surround the vicinity of the outer periphery of the wafer W when the wafer W is placed on the hot plate 2, and is able to discharge gas generated from the wafer W as a result of this PEB treatment.

The first gas supply pipe 5a is connected to a container charged with air (first gas) that has been removed of amine-based hydrogen donors with a chemical filter and for which moisture has been controlled (to a humidity of, for example, 44% to 46%), while the second gas supply pipe 5b is connected to a container charged with an inert gas in the form of, for example, nitrogen (N₂) (second gas), and each gas can be fed to the chamber 3 while independently controlling the flow rates thereof with the first valve 6 and the second valve 7, respectively.

Moisture in the first gas is thought to contribute to the hydrolysis reaction of protecting groups used to substitute the resin using an acid for the catalyst as well as diffusion of acid throughout the resist film, while also contributing to prevention of recombination of protecting groups eliminated in the presence of the acid catalyst with functional groups exhibiting solubility in alkaline solutions.

Consequently, in the case of low humidity, problems occur such as the complete absence of resolution or poor resolution in fine patterns for reasons such as inadequate progression of the hydrolysis reaction by acid catalyst in the resist film, inadequate diffusion of the acid in the resist film, or promotion of reactions causing recombination of protecting groups.

Thus, it is necessary to control the humidity of air introduced into the hot plate. The humidity of air in a clean room is controlled to 44% to 46%. It is therefore also easy to control the humidity of air introduced into the hot plate to 44% to 46%. In addition, if air of the same humidity as that of a clean room is used, there is less likelihood of the occurrence of problems such as condensation of moisture in the hot plate.

It is necessary to terminate the acid-catalyzed reaction immediately after completion of PEB treatment. Supplying the second gas promptly terminates the acid-catalyzed reaction since there is no longer any moisture in the chamber 3.

The second gas is required to be an inert gas not containing moisture. In the case of using N₂ gas, a reaction that terminates the acid-catalyzed reaction occurs as a result of hydrogen ions (H⁺) being trapped by unshared electron pairs of the N atoms. Consequently, the effect of improving dimensional variations is demonstrated even in the case of different treatment times for each unit.

Next, an explanation is provided of carrying out the pattern forming method of the present embodiment using said pattern formation apparatus.

The pattern forming method of the present embodiment comprises a first step for coating a photoresist onto a wafer W, a second step for selectively exposing the wafer W coated with the photoresist, a third step for carrying out baking treatment on the exposed wafer W, and a fourth step for carrying out development treatment on the baked wafer W; wherein, in the third step, the baking treatment is carried out by forming a first atmosphere containing at least moisture, and then replacing the first atmosphere and forming a second atmosphere not containing moisture, followed by continuing the baking treatment.

As shown in FIG. 2A, a hard mask 9 composed of a silicon dioxide film, silicon nitride film, polysilicon film and the like is formed in advance on the surface of a substrate 8 in the wafer W.

Continuing, as shown in FIG. 2B, in the first step, a resist is coated in the form of a film on the hard mask 9, and the coated resist is cured to form a resist film 10.

Resists are commercially available in the form of, for example, members of the TDUR-P series manufactured by Tokyo Ohka Kogyo Co., Ltd. or members of the WKR-PT series manufactured by Wake Pure Chemical Industries, Ltd. For example, 4 to 5 cc of such a resist are dropped onto the hard mask 9 of the wafer W followed by forming a coated film by rotating the wafer W at a speed suitable for obtaining a desired film thickness, and then placing the wafer W on a hot plate (not shown) to evaporate and dry the organic thinner contained in this resist coated film, followed by heat-treating the resist coated film to obtain the resist film 10 having a film thickness of, for example, 7600 Å.

The resist used in the present embodiment is composed by dissolving at least a photo acid generator and a resin in an organic thinner, and more specifically, uses a photo acid generator that generates acid as a result of being decomposed by energy in the form of an electron beam or ultraviolet light and the like, a resin that is made to be insoluble in a developing solution as a result of substituting functional groups, such as hydroxyl groups or carboxyl groups that demonstrate the inherent property of being soluble in the developing solution, of a resin such as polyphenyl or acrylic acid, with protecting groups such as alkyl groups, and an organic thinner such as propylene glycol monomethyl ether acetate, 2-butanone or ethyl lactate.

Although the specific explanation of a chemically amplified resist for KrF has been provided in the present embodiment, a chemically amplified resist for ArF can theoretically also be used. Although the structure of the resin used in a chemically amplified resist for ArF is different, an example of the resin system is an acrylic resin system, while examples of the protecting groups include adamantyl groups.

Continuing, as shown in FIG. 2C, in the second step, the wafer W on which the resist film 10 has been formed is exposed from above through a pre-patterned photomask 11 followed by baking the pattern onto the resist film 10.

Exposure is carried out with a reduction projection exposure apparatus (not shown) at an energy level of, for example, 28 mJ/cm² at a wavelength of 248 rim of an excimer laser light source using a mixed gas of krypton and fluorine (KrF).

An exposed portion 10a is removed in the fourth step to be explained later, and since only an unexposed portion 10b remains on the wafer W, the mask pattern 11a depicted by the photomask 11 can be formed on the resist film 10.

Furthermore, in the case of using a chemically amplified resist for ArF, exposure is carried out using an excimer laser for the exposure light source that uses a mixed gas of argon and fluorine (ArF).

Subsequently, the third step consisting of PEB treatment is carried out in the unit 1.

After the wafer W is carried into the unit 1, the first valve 6 opens at the start of PEB treatment and the first gas is fed into the chamber 3 at a flow rate of, for example, 4.0 l/min. The hot plate 2 is set to a temperature of, for example, 110° C., and treatment is carried out for, for example, 90 seconds.

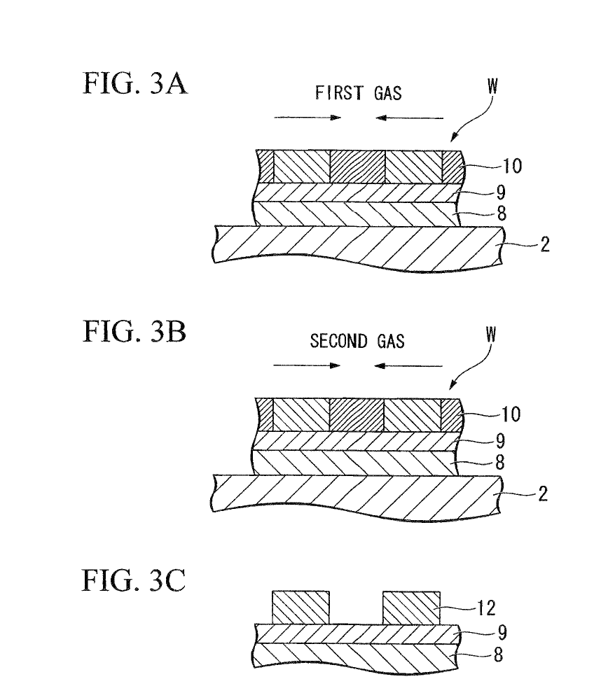

As shown in FIG. 3A, the first gas adequately extends throughout the chamber 3 as a result thereof, and the acid-catalyzed reaction of the chemically amplified resist proceeds smoothly. At the time of completion of PEB treatment, as a result of closing the first valve 6, opening the second valve 7, feeding the second gas at a flow rate of, for example, 4.0 l/min and allowing the wafer W to pause briefly on the hot plate 2 as shown in FIG. 3B without being immediately carried out, the effect of suppressing dimensional variations in the line width of the resist pattern is enhanced.

Finally, in the fourth step, when the exposed portion 10a is removed by development treatment, a resist pattern 12 is formed in the resist film 10 as shown in FIG. 3C.

An aqueous tetramethyl ammonium solution of 2.38% by weight, for example, is used for the developing solution, and development is carried out by forming a puddle on the resist film 10 for, for example, 60 seconds.

As a result of using the second gas after carrying out the acid-catalyzed reaction using the first gas in the third step as in the present embodiment, control is facilitated since the acid-catalyzed reaction is not allowed to proceed further even if the wafer W is present on the hot plate 2. Thus, since the reaction is controlled by controlling the supply of gas even if the treatment time for the wafer W differs among the plurality of units 1, there are no variations in dimensions thereby improving the dimensional uniformity among wafers W.

In addition, in the case of exposing a pattern having a large exposed region in a resist using a resin as described above, since an amount of acid is generated that is greater than the amount of acid required to decompose the protecting groups of the resin in that region, reaction products formed as a result of this decomposition undergo polymerization due to this excess acid, thereby resulting in insolubility even though the protecting groups have been decomposed and eliminated, and causing pattern defects. Even in such cases, if PEB treatment is carried out in an environment in which humidity has been controlled as indicated in the present embodiment, this polymerization reaction is inhibited, thereby making this effective for pattern defects.

The first through fourth steps were carried out in the manner described below using a pattern formation apparatus provided with a unit 1 as shown in FIG. 1.

The wafer W used had a diameter of 30 cm and thickness of 0.78 mm.

<First Step>

In the first step, as shown in FIG. 2, after preliminarily having formed the hard mask 9 on the surface of the substrate 8, the wafer W was coated with a chemically amplified positive type photoresist for KrF (to be simply referred to as a resist) in the first step.

Four to five cc of the resist were dropped onto the hard mask 9 of the wafer W using the TDUR-P007 followed by rotating the wafer W at a speed suitable for obtaining a desired film thickness to form a resist coated film. Moreover, the resist coated film was subjected to heat treatment by placing the wafer W on a hot plate (not shown) to evaporate and dry the organic thinner contained in this resist coated film and form the resist film 10 having a film thickness of 7600 Å.

<Second Step>

Continuing with the second step, the wafer W on which the resist film 10 has been formed was exposed through the photomask 11 preliminarily depicted a mask pattern 11a to bake the pattern onto the resist film 10.

Exposure was carried out with a reduction projection exposure apparatus (not shown) at an energy level of 28 mJ/cm² at a wavelength of 248 nm of an excimer laser light source using a mixed gas of krypton and fluorine (KrF).

<Third Step>

Subsequently, in the third step, post-exposure bake (PEB) treatment was carried out in the unit 1.

A container charged with a first gas in the form of air that has been removed of amine-based hydrogen donors such as ammonia and controlled to a humidity of 44% to 46% was connected to the first gas supply pipe 5a, while a container charged with a second gas in the form of an inert gas of nitrogen (N₂) was connected to the second gas supply pipe 5b.

After carrying wafer W into the unit 1, the first valve 6 was opened and the first gas was fed into the chamber 3 at a flow rate of 4.0 l/min at the start of PEB. The hot plate 2 was set to a temperature of 110° C. and treatment was carried out for 90 seconds.

Following completion of PEB treatment, the first valve 6 was closed and the second valve 7 was opened to feed the second gas into the chamber 3 at the rate of 4.0 l/min, and the wafer W was paused on the hot plate 2 for 60 seconds without being immediately carried out of the chamber 3.

<Fourth Step>

Finally, in the fourth step, the exposed portion 10a was removed by development treatment to form the resist pattern 12 in the resist film 10.

An aqueous tetramethylammonium solution of 2.38% by weight was used for the developing solution, and development was carried out by forming a puddle on the resist film 10 for 60 seconds.

As has been described above, the present embodiment provides a pattern forming method comprising first step for coating a photoresist onto a wafer W, a second step for selectively exposing the wafer W coated with the photoresist, a third step for carrying out baking treatment on the exposed wafer W, and a fourth step for carrying out development treatment on the baked wafer W; wherein, in the third step, the baking treatment is carried out by forming a first atmosphere containing at least moisture, and then replacing the first atmosphere and forming a second atmosphere not containing moisture, followed by continuing the baking treatment, thereby making it possible to suppress variations in line width dimensions of a resist pattern and allow the formation of a satisfactory resist pattern.

While preferred embodiments of the present invention has been described and illustrated above, it should be understood that these are exemplary of the invention and are not to be considered as limiting. Additions, omissions, substitutions and other modifications can be made without departing from the spirit or scope of the present invention. Accordingly, the invention is not to be considered as being limited by the foregoing description, and is only limited by the scope of the appended claims.

1. A pattern forming method comprising:
a first step for coating a photoresist onto a substrate;
a second step for selectively exposing the substrate coated with the photoresist;
a third step for carrying out baking treatment on the exposed substrate; and
a fourth step for carrying out development treatment on the baked substrate,
wherein, in the third step, the baking treatment is carried out by forming a first atmosphere containing at least moisture, and then replacing the first atmosphere and forming a second atmosphere not containing moisture, followed by continuing the baking treatment.

2. The pattern forming method according to claim 1, wherein the first atmosphere is formed from a gas humidified to a humidity of 44% to 46%, and the second atmosphere is an inert gas atmosphere.

3. The pattern forming method according to claim 1, wherein, in the third step, the first atmosphere and the second atmosphere are formed for each of a plurality of exposed substrates.

4. A pattern formation apparatus that carries out a first step for coating a photoresist onto a substrate, a second step for selectively exposing the substrate coated with the photoresist, a third step for carrying out baking treatment on the exposed substrate, and a fourth step for carrying out development treatment on the baked substrate; wherein,
the apparatus comprises at least one unit including a heating section for heating the exposed substrate by placing thereon, a chamber for covering the heating section, an exhaust unit for discharging gas within the chamber to the outside, and a gas supply mechanism for supplying a gas inside the chamber, and
the air supply mechanism in the third step is able to supply a first gas containing at least moisture and then switch to supplying a second gas not containing moisture, and
the baking treatment is carried out by forming a first atmosphere consisting of the first gas and then replacing the first atmosphere and forming a second atmosphere consisting of the second gas, followed by continuing the baking treatment.

5. The pattern formation apparatus according to claim 4, wherein the first gas is a gas humidified to a humidity of 44% to 46%, and the second gas is an inert gas.

6. The pattern formation apparatus according to claim 4, wherein a plurality of the units are provided, and the apparatus has the ability to control the supply of the gas for each of the units.

7. The pattern formation apparatus according to claim 5 wherein a plurality of the units are provided, and the apparatus has the ability to control the supply of the gas for each of the units.

8. The pattern forming method according to claim 2, wherein, in the third step, the first atmosphere and the second atmosphere are formed for each of a plurality of exposed substrates.
